(19) United States
(12) Patent Application Publication
(10) Pub. No.: US 2019/0189824 A1
(43) Pub. Date: Jun. 20, 2019

(54) SOLAR CELL MODULE INCLUDING LIGHT GUIDE MEMBER, AND METHOD OF FABRICATING THE SAME

(71) Applicants: Samsung Electronics Co., Ltd., Suwon-si (KR); RESEARCH & BUSINESS FOUNDATION SUNGKYUNKWAN UNIVERSITY, Suwon-si (KR)

(72) Inventors: Youngjun PARK, Suwon-si (KR); Sang-Woo KIM, Suwon-si (KR); Hong Joon YOON, Suwon-si (KR); Youngin SON, Suwon-si (KR); Ahrum SOHN, Suwon-si (KR)

(21) Appl. No.: 16/217,445

(22) Filed: Dec. 12, 2018

(30) Foreign Application Priority Data
Dec. 15, 2017 (KR) 10-2017-0173583

(51) Int. Cl. H01L 31/054; H01L 31/18; H01L 31/0352; G02B 6/42; H02S 40/22

(52) U.S. Cl. CPC H01L 31/0543; H01L 31/18; H02S 40/22; G02B 6/4295; H01L 31/035218

(57) ABSTRACT

A solar cell module having a light guide member and a method of fabricating the same are provided. The solar cell module includes a light guide member including a light receiving surface for receiving external light and a side surface formed to be inclined to or perpendicular to the light receiving surface, and at least one solar cell mounted on the side surface, the at least one solar cell being configured to receive the external light through the light guide member and perform photoelectric transformation on the received external light. The light guide member includes a plurality of air pores, and the light guide member guides the received external light to a direction of the side surface. The solar cell module may be configured in various manners according to embodiments.

### CROSS-REFERENCE TO RELATED APPLICATION(S)

This application is based on and claims priority under 35 U.S.C. § 119(a) of a Korean patent application number 10-2017-0173583, filed on Dec. 15, 2017, in the Korean Intellectual Property Office, the disclosure of which is incorporated by reference herein its entirety.

### BACKGROUND

### 1. Field

The disclosure relates to a solar cell. More particularly, the disclosure relates to a solar cell module including a light guide member.

### 2. Description of Related Art

As fossil fuels such as petroleum or coal cause environmental contamination, and suffer from upcoming resource exhaustion, more and more interest have been attracted to natural energy that can substitute for the fossil fuels, such as wind power, tidal power, or sunlight. However, there may be difficulty in continuously or safely producing natural energy. For example, the total amount of harvestable energy may be limited according to weather conditions, and even if the weather condition is good, technologies developed so far may have low energy conversion efficiency.

Photovoltaics, which is the process of converting solar energy into power by means of photoelectric transformation devices or the like, is carried out in common homes as well as large-scale power facilities, and may be used as a power source for daily necessities such as a small electronic watch or the like. For example, solar energy may be used through a large-scale facility and also sufficiently in personal livings.

There may be limitations in securing, from solar energy, power enough to use devices (for example, electronic devices including a mobile communication terminal, a tablet personal computer (PC), a laptop computer, and so on) in a user's daily life. For example, considering energy conversion efficiency achieved so far or a use environment, utilization of solar energy as a power source for a user device such as a mobile communication terminal may be limited. In harnessing solar energy, as a light receiving area is wider and a light receiving time is longer, more energy (for example, power) may be produced. However, an individual user may a limit as to securing a sufficient light receiving area and time. Moreover, the user may have difficulty in securing available power during movement.

The above information is presented as background information only to assist with an understanding of the disclosure. No determination has been made, and no assertion is made, as to whether any of the above might be applicable as prior art with regard to the disclosure.

### SUMMARY

Aspects of the disclosure is to address at least the above-mentioned problems and/or disadvantages and to provide at least the advantages described below. Accordingly, an aspect of the disclosure is to provide a solar cell module with improved energy conversion efficiency.

Another aspect of the disclosure is to provide a solar cell module which may further be miniaturized for power production at the same level by improving energy conversion efficiency.

Another aspect of the disclosure is to provide a solar cell module which can easily be carried with an individual user, and supply power to a user device (for example, an electronic device such as a mobile communication terminal, a wearable device, or the like).

Additional aspects will be set forth in part in the description which follows and, in part, will be apparent from the description, or may be learned by practice of the presented embodiments.

In accordance with an aspect of the disclosure, a solar cell module is provided. The solar cell module includes a light guide member comprising a light receiving surface configured to receive external light and a side surface formed to be inclined to or perpendicular to the light receiving surface, and at least one solar cell mounted on the side surface, the at least one solar cell being configured to receive the external light through the light guide member and perform photoelectric transformation on the received external light. The light guide member further comprises a plurality of air pores, the light guide member guides the received external light to a direction of the side surface.

The light guide member may include a quantum dot or dye excited by incident light, thereby guiding incident light in a direction of the solar cell.

In accordance with another aspect of the disclosure, a solar cell module is provided. The solar cell module includes a light guide member comprising a light receiving surface configured to receive external light and a side surface formed to be inclined to or perpendicular to the light receiving surface, the side surface having a transmittance between 40% and 65% for light at a wavelength between 500 nm and 600 nm, and at least one solar cell mounted on the side surface, the at least one solar cell being configured to receive the external light through the light guide member and perform photoelectric transformation on the received external light. The light guide member further comprises a quantum dot or dye excited by incident light, and a plurality of air pores, thereby guiding the received external light to a direction of the side surface.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view illustrating a solar cell module according to an embodiment of the disclosure;

FIG. 2 is a structural sectional view illustrating a solar cell module according to an embodiment of the disclosure;

FIG. 3 is a graph illustrating transmittances of a light guide member in a solar cell module fabricated in a general thermal processing method according to an embodiment of the disclosure;

FIG. 4 is a graph illustrating transmittances of a light guide member in a solar cell module according to an embodiment of the disclosure; and

FIG. 5 is a graph illustrating measured amounts of light traveling in a side direction of a light guide member in a solar cell module according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

Many modifications may be made to the disclosure, and the disclosure may have various embodiments. Specific embodiments of the disclosure are described with reference to the accompanying drawings. However, the embodiments are not intended to limit the disclosure to the particular embodiments, and it is to be understood that the disclosure covers various modifications, equivalents, and alternatives to the embodiments within the scope and spirit of the disclosure.

Ordinal terms such as “first” or “second” may be used to describe, not limiting, various components. These expressions are used to distinguish one component from another component. For example, a first component may be referred to as a second component, and vice versa without departing from the scope of the disclosure. The term ‘and/or’ includes one or a combination of two or more of a plurality of enumerated items.

Relative terms described with respect to what is seen in the drawings, such as “front surface,” “rear surface,” “top surface,” and “bottom surface” may substitute for ordinal numbers such as “first” and “second.” The sequence of ordinal numbers such as “first” and “second” is determined in a mentioned order or an arbitrary order, and may be changed arbitrarily when needed.

The terms as used in the disclosure are provided to merely describe specific embodiments, not intended to limit the scope of the disclosure. It is to be understood that singular forms include plural referents unless the context clearly dictates otherwise. In the disclosure, the term “include” or “have” signifies the presence of a feature, number, operation, component, part, or a combination thereof described in the disclosure, not excluding the presence of one or more other features, numbers, operations, components, parts, or a combination thereof.

Unless otherwise defined, the terms and words including technical or scientific terms used herein may have the same meanings as generally understood by those skilled in the art. The terms as generally defined in dictionaries may be interpreted as having the same or similar meanings as or to contextual meanings of related technology. Unless otherwise defined, the terms should not be interpreted as ideally or excessively formal meanings.

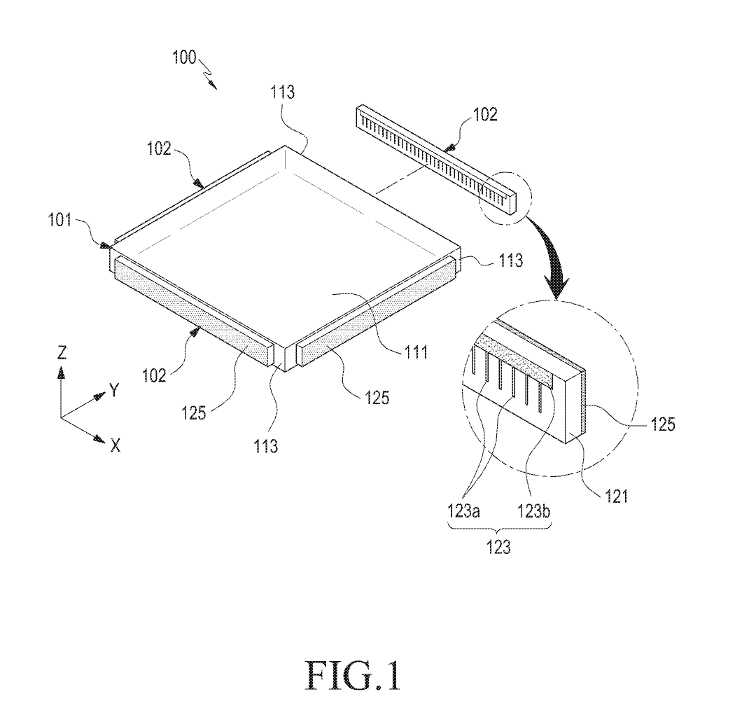

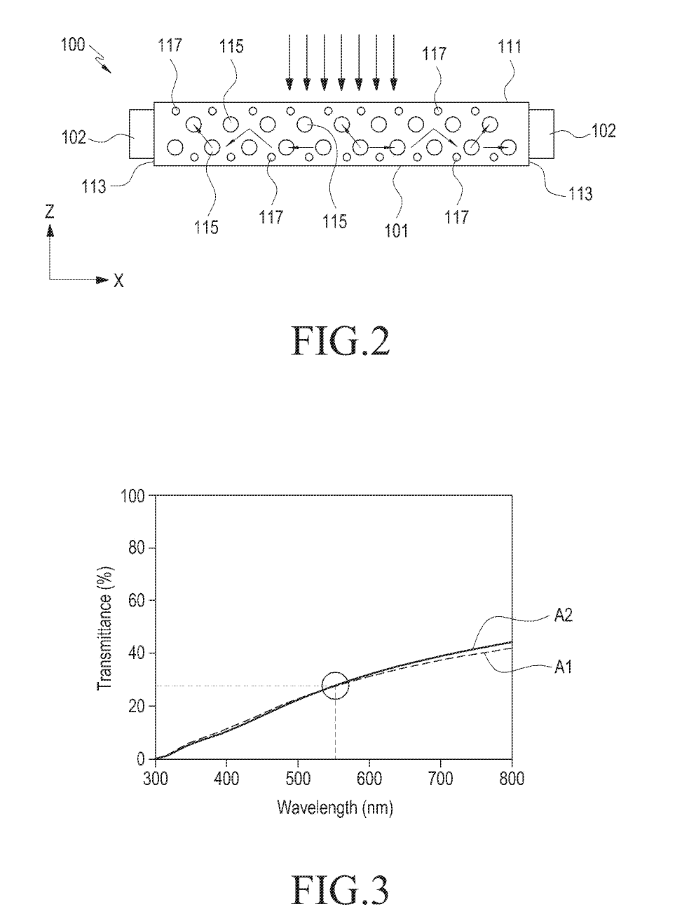

FIG. 1 is a perspective view illustrating a solar cell module according to various embodiments of the disclosure, and FIG. 2 is a structural sectional view illustrating a solar cell module according to various embodiments of the disclosure.

Referring to FIGS. 1 and 2, a solar cell module 100 according to various embodiments of the disclosure may include a light guide member 101 and a solar cell 102. The light guide member 101 may guide incident light in a direction inclined to or substantially parallel to a light receiving surface 111. The solar cell 102 may receive the light guided by the light guide member 101, thereby producing power. In some embodiments, the solar cell module 100 may be surrounded by a sealing material (or a sealing member) (not shown) and thus isolated from an ambient environment (for example, air, moisture, or the like). According to an embodiment, a plurality of solar cell modules may form a solar cell module array, thereby forming a power generator or a consumer generation device. In another embodiment, at least one solar cell module may be mounted in a user device such as a mobile communication terminal or a wearable device, and produce or supply charging power. The number of solar cell modules mounted in the user device may be appropriately determined in consideration of the size, outward design, or the like of the user device.

According to various embodiments, the light guide member 101 may contain polyvinylidene fluoride (PVDF)-based polymer synthetic resin. According to a fabrication process with polymer synthetic resin used as a raw material, the light guide member 101 may contain a piezoelectric/ferroelectric polymer/quantum dot composite. According to an embodiment, the light guide member 101 may include the light receiving surface 111 which is substantially exposed outward, and side surfaces 113 formed to be inclined to or substantially perpendicular to the light receiving surface 111. If the light receiving surface 111 is circular, substantially only one side surface 113 may be formed. If the light receiving surface 111 is shaped into a square, for example, a regular quadrilateral or rectangle, four side surfaces 113 may be formed. According to another embodiment, a surface of the light guide member 101, for example, the light receiving surface 111 may include an anti-reflection coating layer, thereby increasing the incident efficiency of external light.

According to various embodiments, the light guide member 101 may have a predetermined transmittance, for example, 40% to 65%, and include a plurality of air pores 117 therein. In some embodiments, the light guide member 101 may include semiconductor crystals, for example, quantum dots or dye 115 excited by incident light. The quantum dots or the dye 115 included in the light guide member 101 may absorb incident light and then re-emit light according to the wavelength or intensity of the absorbed light. For example, the quantum dots or the dye 115 included in the light guide member 101 may absorb incident light, and emit light in a direction different from an incident direction (for example, a Z-axis direction or its opposite direction). The light guide member 101 may guide received light (or the energy of the received light) in the directions of the side surfaces 113 (for example, an X-axis or Y-axis directions) by using these quantum dots or the dye 115.

According to an embodiment, the plurality of air pores 117 may increase light energy reaching the side surfaces 113 by dispersing or refracting light traveling or guided inside the light guide member 101. For example, the plurality of air pores 117 may suppress transmission of light incident on the light receiving surface 111 through a surface opposite to the light receiving surface 111, or maintain the energy of the light incident on the light receiving surface 111 inside the light guide member 101. The light energy maintained inside the light guide member 101 may reach the side surfaces 113 by repeated absorptions and reemissions of the light energy at the quantum dots or the dye 115.

According to various embodiments, the solar cell 102 may be mounted on at least one of the side surfaces 113, and receive light guided by the light guide member 101, thereby producing power. For example, the solar cell 102 may be implemented in various forms such as a silicon semiconductor-type solar cell, a compound semiconductor-type solar cell, or a stacked solar cell. In some embodiments, the solar cell 102 may be configured in the form of a band having a first electrode 123 and a second electrode 125 disposed respectively on both side surfaces of a semiconductor substrate 121 (for example, a P-N junction semiconductor substrate), and may have a width and a length corresponding to those of one of the side surfaces 113. For example, the solar cell 102 may be fabricated substantially in correspondence with the total area of one of the side surfaces 113. In an embodiment, the solar cell 102 may be disposed on each of the side surfaces 113. For example, the solar cell 102 may receive light travelling in a direction inclined or parallel to the light receiving surface 111, thus producing power.

According to various embodiments, the electrodes of the solar cell 102 may include the first electrode 123 formed on one surface of the semiconductor substrate 121, and the second electrode 125 formed on the other surface of the semiconductor substrate 121. The first electrode 123 may be disposed, substantially facing at least one of the side surfaces 113. In some embodiments, the first electrode 123 may be disposed in direct contact with one of the side surfaces 113. For example, a surface on which the first electrode 123 is formed may be attached (or mounted) on one of the side surfaces 113. The first electrode 123 may include a bar electrode 123b extended in a length direction of the semiconductor substrate 121, and finger electrodes 123a extended from the bar electrode 123b. The finger electrodes 123a may be formed side by side, apart from each other by a predetermined gap, and light guided by the light guide member 101 may reach the semiconductor substrate 121 through areas between the finger electrodes 123a. In an embodiment, the second electrode 125 may include a set of a plurality of bar electrodes arranged side by side or one bar electrode formed substantially across the total area of the other surface of the semiconductor substrate 121.

According to an embodiment, as the transmittance of the light guide member 101 is lower, transmission of received light to the opposite surface of the light receiving surface 111 may be suppressed. Suppression of the amount of light transmitted to the opposite surface of the light receiving surface 111 may increase the amount of light guided to the side surfaces 113. However, if the transmittance is too low, the amount or intensity of the light guided to the side surfaces 113 may also decrease. Since the plurality of air pores 117 are formed in the light guide member 101 in the solar cell module 100 according to various embodiments of the disclosure, the transmittance of the light guide member 101 may be appropriately controlled, and the plurality of air pores 117 scatter and refract received light, thus building an environment in which, for example, the quantum dots or the dye 115 may absorb more light. Therefore, the solar cell module 100 may provide an environment in which light incident on the light guide member 101 may reach the side surfaces 113, for example, the solar cell 102.

According to various embodiments, the light guide member 101 may be molded and fabricated by dissolving polymer powder in a solvent such as solvent or toluene, and then thermally processing the result. Typically, the thermal process for molding and fabricating the light guide member is a process of removing the solvent and hardening the polymer material. The thermal process may start at about 90° C. or 100° C. and proceed for 2 hours. The temperature may gradually be raised up to 140° C. during the thermal process.

FIG. 3 is a graph illustrating transmittances of a light guide member in a solar cell module fabricated in a general thermal processing method according to an embodiment of the disclosure.

Referring to FIG. 3, a curve denoted by “A1” illustrates measured transmittances of a light guide member fabricated by starting a thermal process at 90° C. and performing the thermal process for 2 hours, while gradually raising the temperature up to 140° C. A curve denoted by “A2” illustrates measured transmittances of a light guide member fabricated by starting a thermal process at 100° C. and performing the thermal process for 2 hours, while gradually raising the temperature up to 140° C. As illustrated in FIG. 3, it may be noted that the light guide member fabricated in the general thermal processing method has a transmittance less than about 40% in a visible light area ranging from about 400 nm to 800 nm in wavelength. As noted, the light guide member fabricated in the general thermal processing method has a transmittance of about 27% for light at a wavelength of 500 nm to 600 nm (for example, about 550 nm) at which most light energy is distributed in the visible light area.

As described before, as the transmittance of the light guide member is lower, light transmitted to the opposite surface to the light receiving surface may be suppressed, but the amount of light reaching the side surfaces may also be decreased. However, too high a transmittance leads to transmission of more light to the opposite surface to the light receiving surface, thereby decreasing the amount of light reaching the side surfaces. Accordingly, the light guide member is fabricated to have an appropriate range of transmittances, thereby increasing the light concentration efficiency of the light guide member, for example, the ratio of light reaching the solar cell with respect to the amount of received light.

Since a light guide member (for example, the light guide member 101 in FIG. 1) according to various embodiments of the disclosure includes air pore(s) (for example, the plurality of air pores 117 in FIG. 2), the light guide member may have an appropriate range of transmittances, and maintain light energy within the light guide member 101 by scattering or refracting light by means of the plurality of air pores 117. The light energy maintained in the light guide member 101 may be absorbed and reemitted by quantum dots or dye (for example, the quantum dots or the dye 115 in FIG. 2) so as to reach the side surface(s) 113, for example, the solar cell(s) 102.

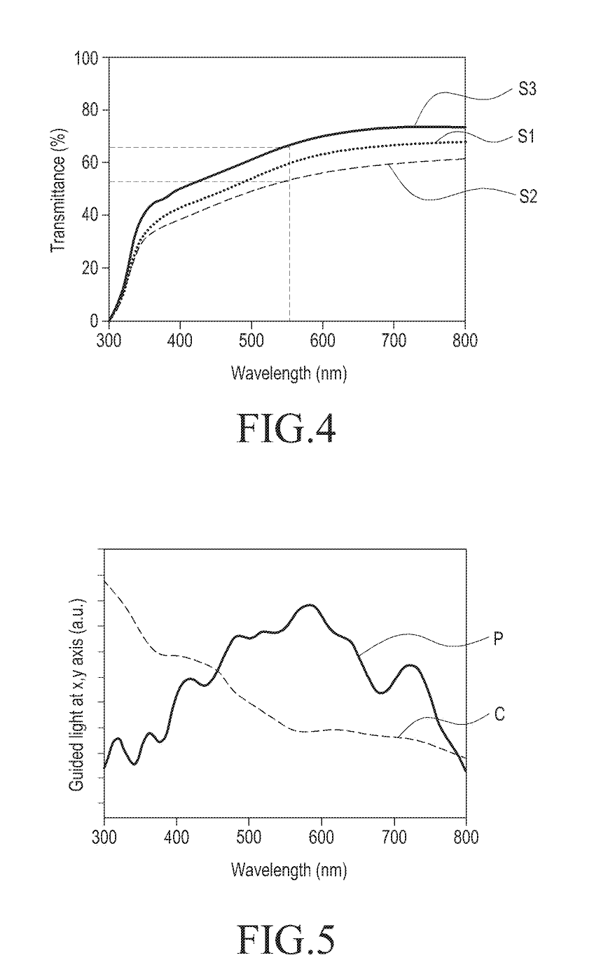

FIG. 4 is a graph illustrating transmittances of a light guide member in a solar cell module according to various embodiments of the disclosure.

Referring to FIG. 4, according to various embodiments of the disclosure, a light guide member (for example, the light guide member 101 in FIG. 1 or FIG. 2) may be fabricated by subjecting polymer powder dissolved in a solvent such as solvent to a primary thermal process (hereinafter, referred to as “soft baking”) in a low temperature area (for example, a temperature area ranging from 60° C. to 80° C.) for 2 to 20 hours, and then a secondary thermal process (hereinafter, referred to as “annealing”) in a high temperature area (for example, a temperature area ranging from 90° C. to 140° C.) for 2 hours. According to an embodiment, a thermal processing temperature may be inversely proportional to a thermal processing time on the whole in the thermal process in a low temperature area, for example, soft baking. For example, a thermal process may be performed at 60° C. for a longer time than at 80° C. Since a thermal process in a high temperature area, for example, annealing may cause oxidation of a polymer material of which a light guide member is formed, the thermal process in a high temperature area may be limited in processing time.

After the light guide member 101 is fabricated by the above process, the solar cell(s) 102 may be mounted on at least one of the side surfaces 113 or the respective side surfaces 113, thereby completing the solar cell module 100.

The graph of FIG. 4 illustrates transmittances of light guide members fabricated under different soft baking conditions. A curve denoted by “S1” illustrates measured transmittances of a light guide member fabricated by performing a thermal process at 65° C. for 6 hours, a curve denoted by “S2” illustrates measured transmittances of a light guide member fabricated by performing a thermal process at 65° C. for 12 hours, and a curve denoted by “S3” illustrates measured transmittances of a light guide member fabricated by performing a thermal process at 65° C. for 18 hours. The transmittances were actually measured by further performing annealing at 90° C. to 140° C. for 2 hours after performing the afore-described soft baking.

As noted from the curves in FIG. 4, compared to a typical light guide member, the light guide member (for example, the light guide member 101 illustrated in FIG. 1 or FIG. 2) according to various embodiments of the disclosure has improved light transmittances across the visible light area. For example, although the transmittance of the light guide member fabricated in the typical thermal processing method is no more than about 27% for light at a wavelength of 500 nm to 600 nm (for example, about 550 nm), it is revealed that the transmittance of the light guide member according to various embodiments of the disclosure has a transmittance of 40% or above, for example, about 50% to 65%.

As described before, an increase in the transmittance of a light guide member means that the amount of light transmitted to the opposite surface to a light receiving surface may increase. According to various embodiments of the disclosure, light incident on the light guide member 101 may be absorbed directly to or re-emitted from the quantum dots or the dye 115, or may be absorbed to or re-emitted from the quantum dots or the dye 115 after being scattered or refracted from the plurality of air pores 117. For example, since the light guide member 101 according to various embodiments of the disclosure suppresses light transmitted to the opposite surface to the light receiving surface 111, guiding received light to the directions of the side surfaces, the light concentration efficiency of the light guide member 101 may be increased.

According to various embodiments, the size, distribution density, and so on of air pores may vary according to a thermal processing temperature or time in soft backing. It was revealed from experiments under different thermal processing temperatures or times that if air pores are too large or have a high distribution density, the transmittance of a light guide member may further be decreased. When a thermal process (for example, soft backing) is performed under the afore-described temperature or time condition, air pores having a diameter of about 0.3 μm to 2 μm are formed, and a good transmittance (e.g., 40% to 65% for light at a wavelength of 500 nm to 600 nm) may be secured for the light guide member.

The results of measuring the amount of light that travels in the directions of the side surfaces, for example, X-axis or Y-axis directions in FIG. 1 and then reaches the solar cell 102 will be described below with reference to FIG. 5.

FIG. 5 is a graph illustrating measured amounts of light traveling in a side direction of a light guide member in a solar cell module according to various embodiments of the disclosure.

Referring to FIG. 5, “a.u.” represents “arbitrary unit.” For example, FIG. 5 compares the amount “C” of light that travels in a direction (for example, an X-axis or Y-axis direction in FIG. 1) perpendicular to the light receiving surface of the light guide member fabricated in the typical thermal processing method, and then reaches a solar cell disposed on a side surface with the amount “P” of light that reaches the solar cell 102 through a light guide member (for example, the light guide member 101 in FIG. 1 or FIG. 2) according to various embodiments of the disclosure.

Referring to FIG. 5, it may be noted that the amount of light that travels in an X-axis or Y-axis direction and reaches the solar cell in the light guide member fabricated in the typical thermal processing method is largest at about 300 nm, and as the wavelength of light increases, the amount of light reaching the solar cell is gradually decreased. On the contrary, it may be noted that the amount of light that travels in an X-axis or Y-axis direction and reaches the solar cell in the light guide member according to various embodiments of the disclosure is largest at about 600 nm, and decreases on the whole at the other wavelengths. For example, it may be noted that the light guide member 101 according to various embodiments of the disclosure guides more light at a wavelength (light at about 400 nm to 800 nm), which facilitates conversion into power in the visible light area. In an embodiment, it may be noted that from the perspective of the whole visible light area (for example, a wavelength area of about 400 nm to 800 nm), the light guide member according to an embodiment of the disclosure guides more light than the typical light guide member.

The results of power production in the light guide member fabricated by the typical thermal process and the light guide member according to various embodiments of the disclosure are listed in Table 1 below. Solar cell modules (for example, the light guide members) were actually fabricated in an area of 3.5 mm*3.5 mm with a thickness of 2.3 mm, and thermal processing conditions are also listed in Table 1.

TABLE 1

| | | Thermal | | |
|---|---|---|---|---|
| | | processing | | Power |
| | | condition | Transparency | generation |
| Typical embodiment | | 140° C./2 hrs | ~20% | ~5.5 mW |
| Embodiment of | 1^{st} sample | 75° C./2 hrs | ~40% | ~6.2 mW |
| the disclosure | | 140° C./2 hrs | | |
| | 2^{nd} | 65° C./18 hrs | ~55% | ~6.5 mW |
| | sample | 100° C./2 hrs | | |

As described before, in a solar cell module according to various embodiments of the disclosure, a solar cell is disposed on a side surface (for example, a side surface 113 in FIG. 1) inclined to or substantially perpendicular to a light receiving surface (the light receiving surface 111 in FIG. 1), and the size or distribution of air pores or the transmittance of a light guide member (for example, the light guide member 101 in FIG. 1) based on the size or distribution of the air pores is controlled. Therefore, light concentration efficiency or photoelectric transformation efficiency may be increased. The increase of light concentration efficiency or photoelectric transformation efficiency may lead to production of higher (more) power for the same light receiving area or further miniaturization for the same power production. As the light concentration efficiency or the photoelectric transformation efficiency increases, the solar cell module according to various embodiments of the disclosure may produce power even in a weather condition with weak sunlight or even from light emitted from indoor lightings. A miniaturized solar cell module may easily be mounted in a small user device such as a mobile communication terminal, and supply charging power to an internal battery.

According to various embodiments of the disclosure, a solar cell module may include a light guide member including a light receiving surface for receiving external light, and a side surface formed to be inclined to or perpendicular to the light receiving surface, and at least one solar cell mounted on the side surface, and configured to receive external light through the light guide member and perform photoelectric transformation on the received light. The light guide member may include a plurality of air pores, and guide the received light to a direction of the side surface.

According to various embodiments, the light guide member may include a piezoelectric/ferroelectric polymer/quantum dot composite.

According to various embodiments, the light guide member may include a piezoelectric/ferroelectric polymer/quantum dot composite which is thermally processed at 60° C. to 80° C. for 2 to 20 hours.

According to various embodiments, the light guide member may include a piezoelectric/ferroelectric polymer/quantum dot composite which is thermally processed at 60° C. to 80° C. for 2 to 20 hours and then at 90° C. to 140° C. for 2 hours.

According to various embodiments, the light guide member may include a quantum dot or dye excited by incident light.

According to various embodiments, the light guide member may have a transmittance of 40% to 65% for light at a wavelength of 500 nm to 600 nm.

According to various embodiments, the air pores may have a diameter of 0.3 μm to 2 μm.

According to various embodiments, the at least one solar cell may include at least one of a silicon semiconductor-type solar cell, a compound semiconductor-type solar cell, or a stacked solar cell.

According to various embodiments, the at least one solar cell may be in the form of a band extended along the side surface.

According to various embodiments of the disclosure, a solar cell module may include a light guide member including a light receiving surface for receiving external light, and a side surface formed to be inclined to or perpendicular to the light receiving surface, and having a transmittance of 40% to 65% for light at a wavelength of 500 nm to 600 nm, and at least one solar cell mounted on the side surface, and configured to receive external light through the light guide member and perform photoelectric transformation on the received light. The light guide member may include a quantum dot or dye excited by incident light, and a plurality of air pores, thereby guiding the received light to a direction of the side surface.

According to various embodiments, the at least one solar cell may be in the form of a band extended along the side surface.

According to various embodiments of the disclosure, a method of fabricating a solar cell module may include preparing a light guide member including a light receiving surface for receiving external light, and a side surface formed to be inclined to or perpendicular to the light receiving surface, and engaging the light guide member with at least one solar cell mounted on the side surface, and configured to receive external light through the light guide member and perform photoelectric transformation on the received light. The light guide member may include a plurality of air pores, and guides the received light to a direction of the side surface.

According to various embodiments, the light guide member may include a piezoelectric/ferroelectric polymer/quantum dot composite.

According to various embodiments, the light guide member may include a piezoelectric/ferroelectric polymer/quantum dot composite which is thermally processed at 60° C. to 80° C. for 2 to 20 hours.

According to various embodiments, the light guide member may include a piezoelectric/ferroelectric polymer/quantum dot composite which is thermally processed at 60° C. to 80° C. for 2 to 20 hours and then at 90° C. to 140° C. for 2 hours.

According to various embodiments, the light guide member may include a quantum dot or dye excited by incident light.

According to various embodiments, the light guide member may have a transmittance of 40% to 65% for light at a wavelength of 500 nm to 600 nm.

According to various embodiments, the air pores may have a diameter of 0.3 μm to 2 μm.

According to various embodiments, the at least one solar cell may include at least one of a silicon semiconductor-type solar cell, a compound semiconductor-type solar cell, or a stacked solar cell.

According to various embodiments, the at least one solar cell may be in the form of a band extended along the side surface.

As is apparent from the foregoing description, according to various embodiments of the disclosure, since a solar cell module includes air pores in a light guide member that receives external light and guides the light to a solar cell, light can be guided in a direction different from an incident direction. For example, received light is guided to the solar cell disposed on a side surface of the light guide member by means of the light guide member with the air pores, thereby increasing photoelectric transformation efficiency.

The solar cell module according to various embodiments of the disclosure has improved photoelectric transformation efficiency and thus may be miniaturized even for the same power production. Therefore, the solar cell module may easily be mounted in a mobile communication terminal or a wearable device.

Due to increased reception efficiency of external light, the solar cell module according to various embodiments of the disclosure may produce power even in a weather condition with weak sunlight or an indoor lighting environment. For example, the solar cell module according to various embodiments of the disclosure may be mounted in a user device and supply power to the user device.

While the disclosure has been shown and described with reference to certain various embodiments thereof, it will be understood by those skilled in the art that various changes in form and details may be made therein without departing from the spirit and scope of the disclosure as defined by the appended claims and their equivalents.

What is claimed is:

1. A solar cell module comprising:
a light guide member comprising:
a light receiving surface configured to receive external light, and
a side surface formed to be inclined to or perpendicular to the light receiving surface; and
at least one solar cell mounted on the side surface, the at least one solar cell being configured to receive the external light through the light guide member and perform photoelectric transformation on the received external light,
wherein the light guide member further comprises a plurality of air pores, and
wherein the light guide member guides the received external light to a direction of the side surface.

2. The solar cell module of claim 1, wherein the light guide member further comprises a piezoelectric/ferroelectric polymer/quantum dot composite.

3. The solar cell module of claim 1, wherein the light guide member further comprises a piezoelectric/ferroelectric polymer/quantum dot composite which is thermally processed at a temperature between 60° C. and 80° C. for a time period between 2 and 20 hours.

4. The solar cell module of claim 1, wherein the light guide member further comprises a piezoelectric/ferroelectric polymer/quantum dot composite which is thermally processed at a first temperature between 60° C. and 80° C. for a first time period between 2 and 20 hours and then at a second temperature between 90° C. and 140° C. for a second time period of 2 hours.

5. The solar cell module of claim 1, wherein the light guide member further comprises a quantum dot or dye excited by incident light.

6. The solar cell module of claim 1, wherein the light guide member has a transmittance between 40% and 65% for light at a wavelength between 500 nm and 600 nm.

7. The solar cell module of claim 1, wherein the plurality of air pores comprise a diameter between 0.3 μm and 2 μm.

8. The solar cell module of claim 1, wherein the at least one solar cell comprises at least one of a silicon semiconductor-type solar cell, a compound semiconductor-type solar cell, or a stacked solar cell.

9. The solar cell module of claim 1, wherein the at least one solar cell is in a form of a band extended along the side surface.

10. A solar cell module comprising:
a light guide member comprising:
a light receiving surface configured to receive external light, and
a side surface formed to be inclined to or perpendicular to the light receiving surface, the side surface having a transmittance between 40% and 65% for light at a wavelength between 500 nm and 600 nm; and
at least one solar cell mounted on the side surface, the at least one solar cell being configured to receive the external light through the light guide member and perform photoelectric transformation on the received external light,
wherein the light guide member further comprises a quantum dot or dye, which is excited by incident light, and a plurality of air pores thereby guiding the received external light to a direction of the side surface.

11. The solar cell module of claim 10, wherein the at least one solar cell is in a form of a band extended along the side surface.

12. A method of fabricating a solar cell module, the method comprising:
preparing a light guide member that comprises a light receiving surface configured to receive external light, and a side surface formed to be inclined to or perpendicular to the light receiving surface; and
engaging the light guide member with at least one solar cell mounted on the side surface, the at least one solar cell being configured to receive the external light through the light guide member and perform photoelectric transformation on the received external light,
wherein the light guide member further comprises a plurality of air pores, and
wherein the light guide member guides the received external light to a direction of the side surface.

13. The method of claim 12, wherein the light guide member further comprises a piezoelectric/ferroelectric polymer/quantum dot composite.

14. The method of claim 12, wherein the light guide member further comprises a piezoelectric/ferroelectric polymer/quantum dot composite which is thermally processed at a temperature between 60° C. and 80° C. for a time period between 2 and 20 hours.

15. The method of claim 12, wherein the light guide member further comprises a piezoelectric/ferroelectric polymer/quantum dot composite which is thermally processed at a first temperature between 60° C. and 80° C. for a first time period between 2 and 20 hours and then at a second temperature between 90° C. and 140° C. for a second time period of 2 hours.

16. The method of claim 12, wherein the light guide member further comprises a quantum dot or dye excited by incident light.

17. The method of claim 12, wherein the light guide member has a transmittance between 40% and 65% for light at a wavelength between 500 nm and 600 nm.

18. The method of claim 12, wherein the plurality of air pores comprise a diameter between 0.3 μm and 2 μm.

19. The method of claim 12, wherein the at least one solar cell comprises at least one of a silicon semiconductor-type solar cell, a compound semiconductor-type solar cell, or a stacked solar cell.

20. The method of claim 12, wherein the at least one solar cell is in a form of a band extended along the side surface.
